(19) United States
(12) Patent Application Publication
(10) Pub. No.: US 2026/0237433 A1
(43) Pub. Date: Aug. 13, 2026

(54) SEMICONDUCTOR STORAGE DEVICE

(71) Applicant: Kioxia Corporation, Tokyo (JP)

(72) Inventor: Kazuki OKAWA, Yokohama Kanagawa (JP)

(73) Assignee: Kioxia Corporation, Tokyo (JP)

(21) Appl. No.: 19/320,930

(22) Filed: Sep. 5, 2025

(30) Foreign Application Priority Data
Feb. 7, 2025 (JP) 2025-019110

(51) Int. Cl. G11C 13/00

(52) U.S. Cl. CPC G11C 13/0069; G11C 13/004; G11C 2013/0057

(57) ABSTRACT

A semiconductor storage device includes a first wiring; a second wiring; a memory cell; a sense amplifier configured to perform a read operation on the memory cell; and a control circuit, wherein the control circuit is configured to perform; a first read operation during a first sensing time in a first read period, a first write operation for wiring the memory cell having undergone the first read operation to a first state in the first write period, a second read operation during a second sensing time different from the first sensing time on the memory cell having undergone the first write operation in a second read period, and a discrimination operation of a state of the memory cell by comparing a first read result obtained by the first read operation with a second read result obtained by the second read operation in a discrimination period.

### CROSS REFERENCE TO RELATED APPLICATIONS

This application claims the benefit of priority to Japanese Patent Application No. 2025-019110, filed on Feb. 7, 2025, the entire contents of which are incorporated herein by reference.

### FIELD

An embodiment of the present disclosure relates to a semiconductor storage device.

### BACKGROUND

A semiconductor storage device in which variable resistance memory elements and the like are integrated on a semiconductor substrate has been proposed.

### BRIEF DESCRIPTION OF DRAWINGS

FIG. 1 is a block diagram showing an overall configuration of a semiconductor storage device according to an embodiment.

FIG. 2 is a perspective view schematically showing a configuration of a semiconductor storage device according to an embodiment.

FIG. 3 is a cross-sectional view schematically showing a configuration of a variable resistance element according to an embodiment.

FIG. 4 is a diagram showing electrical characteristics of a switching element according to an embodiment.

FIG. 5 is a diagram showing electrical characteristics during a read operation of a memory cell according to an embodiment.

FIG. 6 is a block diagram showing a functional configuration of a discrimination circuit included in a semiconductor storage device according to an embodiment.

FIG. 7 is a circuit diagram for explaining a read operation of a semiconductor storage device according to an embodiment.

FIG. 8 is a diagram for explaining a read operation of a semiconductor storage device according to an embodiment.

FIG. 9 is a diagram for explaining a read operation of a semiconductor storage device according to an embodiment.

FIG. 10 is a diagram for explaining a read operation of a semiconductor storage device according to a comparative example.

FIG. 11 is a diagram for explaining a read operation of a semiconductor storage device according to an embodiment.

FIG. 12 is a diagram for explaining a read operation of a semiconductor storage device according to an embodiment.

### DESCRIPTION OF EMBODIMENTS

A semiconductor storage device according to an embodiment of the present invention includes a first wiring; a second wiring; a memory cell configured to be electrically connected to the first wiring and the second wiring between the first wiring and the second wiring; a sense amplifier configured to be electrically connected to the second wiring and configured to perform a read operation on the memory cell; and a control circuit, wherein the control circuit is configured to perform; a first read operation during a first sensing time in a first read period, a first write operation for writing the memory cell having undergone the first read operation to a first state in the first write period, a second read operation during a second sensing time different from the first sensing time on the memory cell having undergone the first write operation in a second read period, and a discrimination operation of a state of the memory cell by comparing a first read result obtained by the first read operation with a second read result obtained by the second read operation in a discrimination period.

The present disclosure provides a semiconductor storage device capable of reducing a size of a circuit required for a read operation.

Hereinafter, a semiconductor storage device according to the present embodiment will be described in detail with reference to the drawings. In the following description, elements having substantially the same functions and configurations are denoted by the same reference signs, and will be described redundantly only when necessary. Each of the embodiments described below exemplifies a device and a method for embodying a technical idea of the present embodiment. The technical idea of the embodiment is not to limit the material, shape, structure, arrangement, or the like of the constituent parts as follows. The technical idea of the embodiment may be modified in various ways within the scope of the claims.

In the embodiments of the present disclosure, a direction from a variable resistance element 101 toward a switching element 102 is referred to as “on” or “above.” Conversely, a direction from the switching element 102 toward the variable resistance element 101 is referred to as “under” or “below.” As described above, for convenience of explanation, the term “above” or “below” is used to describe the configuration, but the variable resistance element 101 and the switching element 102 may be arranged in a vertical relationship opposite to that shown in the figure. In the following explanation, for example, the expression “the switching element 102 above the variable resistance element 101” merely describes the vertical relationship between the variable resistance element 101 and the switching element 102 as described above, and other members may be arranged between the variable resistance element 101 and the switching element 102. The term “above” or “below” means a stacking order in a structure in which a plurality of layers is stacked. When expressed as a bit line BL above a word line WL, the word line WL and the bit line BL may not overlap in a plan view. On the other hand, when expressed as the bit line BL vertically above the word line WL, this indicates a positional relationship in which the word line WL and the bit line BL overlap in a plan view.

In the present specification, the expressions “α includes A, B or C,” “α includes any of A, B and C,” and “α includes one selected from a group consisting of A, B, and C” do not exclude the case where α includes a plurality of combinations of A to C unless otherwise specified. Furthermore, these expressions do not exclude the case where α includes other elements.

In the following explanation, a “voltage” refers to a potential difference between two terminals, but a “voltage” may refer to a potential relative to a ground voltage GND (e.g., 0 V).

### 1. First Embodiment

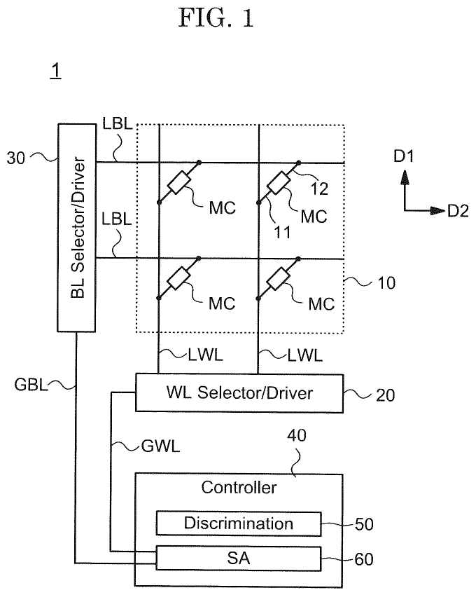

A semiconductor storage device according to a first embodiment will be described with reference to FIG. 1 to FIG. 11.

### 1-1. Overall Configuration of Semiconductor Storage Device

An overall configuration of the semiconductor storage device according to the first embodiment will be described with reference to FIG. 1. FIG. 1 is a block diagram showing an overall configuration of the semiconductor storage device according to an embodiment. As shown in FIG. 1, a semiconductor storage device 1 includes a memory cell array 10, a word line selection/driving circuit 20 (WL Selector/Driver), a bit line selection/driving circuit 30 (BL Selector/Driver), and a control circuit 40 (Controller).

A plurality of memory cells MC, a plurality of local word lines LWL, and a plurality of local bit lines LBL are arranged in the memory cell array 10. Each local word line LWL extends in a direction D1. Each local bit line LBL extends in a direction D2. Each memory cell MC is provided between the local word line LWL and the local bit line LBL, and is configured to be electrically connected to the local word line LWL and the local bit line LBL. The memory cell MC is a two-terminal memory cell. A first terminal 11 of the memory cell MC is connected to the local word line LWL. A second terminal 12 of the memory cell MC is connected to the local bit line LBL. Although details will be described later, the local word line LWL and the local bit line LBL intersect each other. The memory cell MC is provided at a position where the local word line LWL and the local bit line LBL intersect each other. The local bit line LBL may be referred to as a “first wiring.” The local word line LWL may be referred to as a “second wiring.”

FIG. 1 exemplifies a configuration in which the direction D1 and the direction D2 are perpendicular to each other. However, the direction D1 and the direction D2 may intersect each other at an angle that is not perpendicular to each other. In FIG. 1, a configuration in which the local word line LWL extends linearly in the direction D1 is exemplified. However, the local word line LWL may not be linear. The local word line LWL only needs to extend in the direction D1 when the local word line LWL is viewed as a whole. FIG. 1 exemplifies a configuration in which the local bit line LBL extends linearly in the direction D2. However, the local bit line LBL may not be linear. The local bit line LBL only needs to extend in the direction D2 when the entire local bit line LBL is viewed as a whole.

The memory cell MC to be subjected to a write operation and a read operation is designated by selecting one local word line LWL and one local bit line LBL from the plurality of local word lines LWL and the plurality of local bit lines LBL. Specifically, a predetermined current flows through the memory cell MC by applying a predetermined voltage to the specific local word line LWL and the local bit line LBL. The predetermined current flows through the memory cell MC, and then the write operation and the read operation are performed on the memory cell MC. Further, in the following explanation, the read operation for the memory cell MC may be referred to as a “sense operation” or a “sense amplifier operation.”

The word line selection/driving circuit 20 is provided at a position adjacent to the memory cell array 10 in the direction D1. Each local word line LWL is connected to the word line selection/driving circuit 20.

The bit line selection/driving circuit 30 is provided at a position adjacent to the memory cell array 10 in the direction D2. Each local bit line LBL is connected to the bit line selection/driving circuit 30.

The control circuit 40 is connected to the word line selection/driving circuit 20 and the bit line selection/driving circuit 30. The control circuit 40 includes a discrimination circuit 50 (Discrimination) and a sense amplifier 60 (SA). The control circuit 40 is connected to the word line selection/driving circuit 20 via a global word line GWL and is connected to the bit line selection/driving circuit 30 via a global bit line GBL. More specifically, the global word line GWL and the global bit line GBL are connected to the sense amplifier 60. Although details will be described later, the sense amplifier 60 performs the read operation on the memory cell MC.

The control circuit 40 performs the write operation or the read operation in response to a command. The control circuit 40 supplies a control signal to the word line selection/driving circuit 20 and the bit line selection/driving circuit 30 in response to an address specified in the write operation and the read operation. In response to the control signal, the word line selection/driving circuit 20 and the bit line selection/driving circuit 30 select the local word line LWL and the local bit line LBL corresponding to the specified address, respectively. The word line selection/driving circuit 20 and the bit line selection/driving circuit 30 apply a write voltage or a read voltage to the selected local word line LWL and local bit line LBL, respectively.

Although a configuration in which one global word line GWL and one global bit line GBL are connected to the control circuit 40 is exemplified in the present embodiment, the configuration is not limited to this configuration. For example, a plurality of global word lines GWL and a plurality of global bit lines GBL may be connected to the control circuit 40. The plurality of global word lines GWL and the plurality of global bit lines GBL may be connected to different memory cell arrays 10.

The global word line GWL can be connected to the plurality of local word lines LWL. The global bit line GBL can be connected to the plurality of local bit lines LBL. That is, the local word line LWL is connected to the sense amplifier 60 via the global word line GWL. Similarly, the local bit line LBL is connected to the sense amplifier 60 via the global bit line GBL.

The discrimination circuit 50 discriminates a data value stored in the memory cell MC based on the voltage (read voltage) of the memory cell MC obtained by the read operation. Although details will be described later, the memory cell MC includes the variable resistance element 101 and stores binary data depending on a resistance state (low resistance state or high resistance state) of the variable resistance element 101. The data stored in the memory cell MC is discriminated by discriminating the resistance state of the variable resistance element 101 by the discrimination circuit 50.

### 1-2. Configuration of Memory Cell Array 10

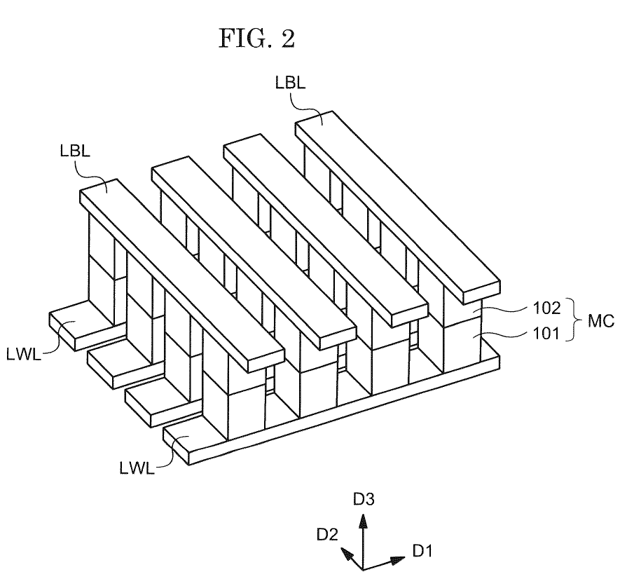

FIG. 2 is a perspective view schematically showing a configuration of a memory cell according to an embodiment. As shown in FIG. 2, the memory cell MC is provided above (direction D3) the local word line LWL. The local bit line LBL is provided above (direction D3) the memory cell MC. In other words, the memory cell MC is provided between the local word line LWL and the local bit line LBL in a region where the local word line LWL and the local bit line LBL intersect.

The memory cell MC includes the variable resistance element 101 and the switching element 102. The variable resistance element 101 and the switching element 102 are connected in series between the local word line LWL and the local bit line LBL. The variable resistance element 101 is provided on the local word line LWL side, and the switching element 102 is provided on the local bit line LBL side.

The variable resistance element 101 is a non-volatile memory element that can be switched to a low resistance state or a high resistance state. The low resistance state of the variable resistance element 101 may be referred to as a “first low resistance state.” The high resistance state of the variable resistance element 101 may be referred to as a “first high resistance state.” In the present embodiment, a configuration in which a magnetoresistance effect element including a magnetic tunnel junction (MTJ) is used as the variable resistance element 101 will be described. Hereinafter, the magnetoresistance effect element may be referred to as an MTJ element. The MTJ element is a memory element in which a resistance (tunnel resistance) changes due to a tunnel effect in an insulating layer depending on a relationship (parallel or non-parallel) between magnetization directions of two adjacent magnetic layers via the insulating layer. That is, the MTJ element includes a plurality of resistance states (resistance values) depending on the relative relationship (magnetization arrangement) between the direction of magnetization of one magnetic layer and the direction of magnetization of the other magnetic layer.

The switching element 102 is a two-terminal device. The switching element is switched to a low resistance state or a high resistance state depending on the voltage applied to the two terminals. The low resistance state of the switching element 102 may be referred to as a “second low resistance state.” The high resistance state of the switching element 102 may be referred to as the “second high resistance state.” The resistance of the second low resistance state is lower than the resistance of the first low resistance state of the variable resistance element 101. The resistance of the second high resistance state is higher than the resistance of the first high resistance state of the variable resistance element 101. That is, in the case where the switching element 102 is in the second high resistance state, the resistance of the memory cell MC is substantially determined by the resistance of the switching element 102. On the other hand, in the case where the switching element 102 is in the second low resistance state, the resistance of the memory cell MC is substantially determined by the resistance of the variable resistance element 101. In the case where the switching element 102 is in the second high resistance state, it can be said that the memory cell MC is in a non-conductive state. In the case where the switching element 102 is in the second low resistance state, it can be said that the memory cell MC is in a conductive state.

Unlike the configuration of FIG. 2, the variable resistance element 101 may be provided on the local bit line LBL side. The switching element 102 may be provided on the local word line LWL side. That is, the variable resistance element 101 and the switching element 102 may be interchanged. On the other hand, the local word line LWL may be provided above (direction D3) the switching element 102. The local bit line LBL may be provided below the variable resistance element 101 (opposite to the direction D3). That is, the local word line LWL and the local bit line LBL may be interchanged. Other members may be provided between the local word line LWL and the variable resistance element 101. Similarly, other members may be provided between the local bit line LBL and the switching element 102.

Although a configuration in which the MTJ element is used as the variable resistance element 101 is described in the present embodiment, variable resistance elements other than the MTJ element may be used as the variable resistance element 101. For example, a resistive random access memory element (ReRAM), a ferroelectric random access memory (FeRAM), an organic memory, and a phase change random access memory element (PRAM) may be used as the variable resistance element 101.

Although the two-terminal memory element is exemplified as the memory cell MC in the present embodiment, the configuration is not limited to this configuration. For example, a three-terminal memory element such as a transistor may be used as the memory cell MC. In this case, the memory element may store data having three or more values.

### 1-3. Configuration of MTJ Element

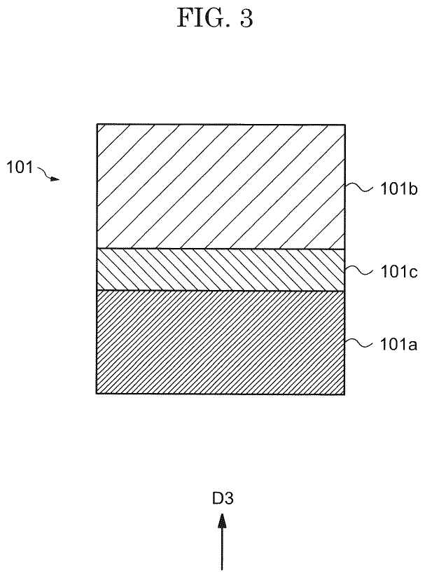

FIG. 3 is a cross-sectional view schematically showing a configuration of a variable resistance element according to an embodiment. As shown in FIG. 3, the MTJ element used as the variable resistance element 101 includes a storage layer 101a, a reference layer 101b, and a tunnel barrier layer 101c. The storage layer 101a is a ferromagnetic layer having a first magnetic property. The reference layer 101b is a ferromagnetic layer having a second magnetic property. The tunnel barrier layer 101c is a nonmagnetic layer. A magnetization direction of the storage layer 101a is variable. The magnetization direction of the reference layer 101b is fixed. The write current supplied to the storage layer 101a changes the magnetization direction of the storage layer 101a. A direction of the write current determines the magnetization direction of the storage layer 101a. On the other hand, even when the write current is supplied to the reference layer 101b, the magnetization direction of the reference layer 101b does not change. The tunnel barrier layer 101c is an insulating layer. The expression “the magnetization direction is variable” means that the magnetization direction can be changed between before the write current is supplied (before writing) and after the write current is supplied (after writing). “The magnetization direction is fixed” means that the magnetization direction does not change between before the write current is supplied (before writing) and after the write current is supplied (after writing).

In the case where the magnetization direction of the storage layer 101a is parallel to the magnetization direction of the reference layer 101b (in the case where the magnetization direction is the same direction), the MTJ element is in the low resistance state. In the case where the magnetization direction of the storage layer 101a is antiparallel to the magnetization direction of the reference layer 101b (in the case where the magnetization direction is the opposite direction), the MTJ element is in the high resistance state. As described above, since the resistance state (low resistance state or high resistance state) is controlled by the magnetization direction of the storage layer 101a, the MTJ element can store different binary data based on the resistance state.

Although FIG. 3 exemplifies a configuration in which a bottom-free type MTJ element in which the storage layer 101a is provided below the reference layer 101b is used as the variable resistance element 101, the configuration is not limited to this configuration. A top-free type MTJ element in which the storage layer 101a is provided above the reference layer 101b may be used as the variable resistance element 101. The MTJ element may further include a shift canceling layer that cancels a magnetic field applied from the reference layer 101b to the storage layer 101a.

### 1-4. Electrical Characteristics of Switching Element

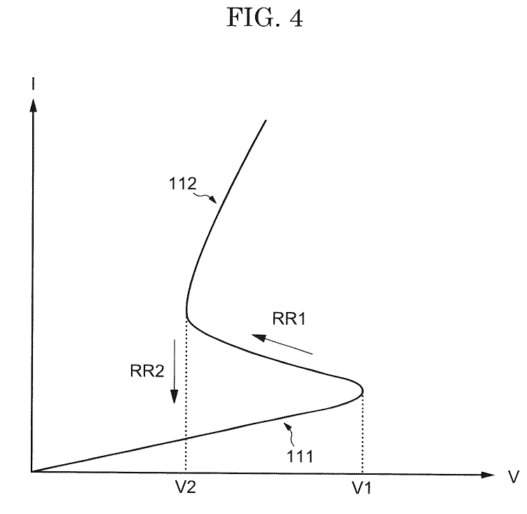

FIG. 4 is a diagram showing the electrical characteristics of a two-terminal switching element according to an embodiment. As shown in FIG. 4, when the voltage applied between the two terminals increases to reach a first voltage V1, the switching element 102 is switched from a high resistance state 111 to a low resistance state 112. The switching element 102 has characteristics that when the switching element 102 is switched to the low resistance state 112, the voltage between the two terminals shifts to a second voltage V2 lower than the first voltage V1, and the current rapidly increases. Further, the switching element 102 has characteristics that when the voltage applied between the two terminals decreases to reach the second voltage V2, the switching element 102 is switched from the low resistance state 112 to the high resistance state 111. That is, the switching element 102 follows a negative resistance region between the voltage V1 and the voltage V2 (arrow RR1) when switched from the high resistance state 111 to the low resistance state 112, but transitions to the high resistance state 111 without following the negative resistance region when switched from the low resistance state 112 to the high resistance state 111 (arrow RR2). The switching element 102 exhibits mutually symmetric electrical characteristics in both directions (positive and negative directions).

The switching element 102 of the present embodiment has characteristics that resistance decreases rapidly at the voltage V1, and accordingly, the applied voltage decreases rapidly, and the current increases (snap-back), as an example. The switching element 102 of the present embodiment is the two-terminal switching element. Material compositions used for the switching element having such characteristics are appropriately selected according to the characteristics of the memory cell.

A predetermined voltage is applied between the local word line LWL and the local bit line LBL and then the switching element 102 is switched to the low resistance state, and the write operation and the read operation for the variable resistance element 101 can be performed.

### 1-5. Electrical Characteristics of Memory Cell Mc

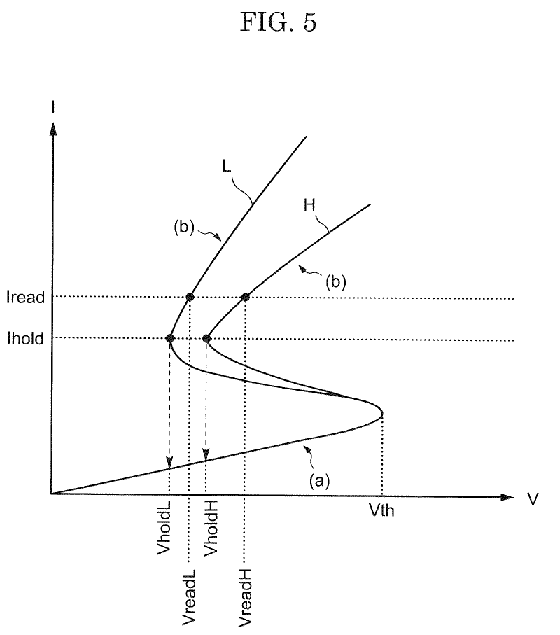

FIG. 5 is a diagram schematically showing electrical characteristics of the selected memory cell MC during the read operation. In FIG. 5, the horizontal axis represents the voltage between the two terminals of the selected memory cell MC (the voltage applied between the local word line LWL and the local bit line LBL), and the vertical axis represents the current flowing through the selected memory cell MC. The characteristic (L) is a characteristic when the variable resistance element 101 is in the low resistance state. The characteristic (H) is a characteristic when the variable resistance element 101 is in the high resistance state.

As described above, the resistance of the switching element 102 in the high resistance state is higher than that of the variable resistance element 101 in the high resistance state. In this case, the resistance of the memory cell MC is substantially determined by the resistance of the switching element 102. Therefore, the electrical characteristics (corresponding to the characteristic part (a)) of the memory cell MC before the switching element 102 is switched from the high resistance state to the low resistance state are substantially the same even if the variable resistance element 101 is in the low resistance state or in the high resistance state. That is, a voltage (a threshold voltage Vth) applied between the two terminals of the memory cell MC when the switching element 102 is switched from the high resistance state to the low resistance state is substantially the same even if the variable resistance element 101 is in the low resistance state or in the high resistance state.

On the other hand, since the resistance of the switching element 102 is lower than the resistance of the variable resistance element 101 in the low resistance state, the resistance of the memory cell MC is determined by the resistance of the variable resistance element 101 after the switching element 102 is switched from the high resistance state to the low resistance state. Therefore, in the electric characteristics (corresponding to the characteristic part (b)) of the memory cell MC after the switching element 102 is switched from the high resistance state to the low resistance state, the electric characteristics when the variable resistance element 101 is in the low resistance state is different from the electric characteristics when the variable resistance element 101 is in the high resistance state. Specifically, for the voltage-current gradient in the characteristic part (b), the gradient in the case where the variable resistance element 101 is in the high resistance state is smaller than the gradient in the case where the variable resistance element 101 is in the low resistance state.

As shown in FIG. 5, with respect to a read current Iread in the read operation, the read voltage when the variable resistance element 101 is in the low resistance state is VreadL, and the read voltage when the variable resistance element 101 is in the high resistance state is VreadH. The read voltage VreadL is smaller than the read voltage VreadH. The resistance state (low resistance state or high resistance state) of the variable resistance element 101 can be discriminated based on the difference between the read voltage VreadL and the read voltage VreadH.

In FIG. 5, a hold current Ihold is a current flowing through the memory cell MC when the switching element 102 is switched from the low resistance state to the high resistance state. A hold voltage Vhold is a voltage applied between two terminals of the memory cell MC when the hold current Ihold flows through the memory cell MC. The hold voltage when the variable resistance element 101 is in the low resistance state is VholdL. The hold voltage when the variable resistance element 101 is in the high resistance state is VholdH. In the case where the hold voltages VholdL and VholdH are not specifically distinguished, they are simply referred to as the hold voltage Vhold.

### 1-6. Functional Configuration of Discrimination Circuit

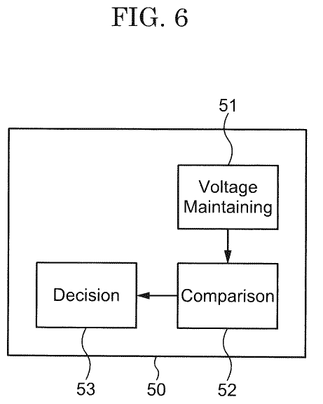

FIG. 6 is a block diagram showing a functional configuration of the discrimination circuit included in the semiconductor storage device according to an embodiment. As shown in FIG. 6, the discrimination circuit 50 includes a voltage maintaining unit 51 (Voltage Maintaining), a comparison unit 52 (Comparison), and a discrimination unit 53 (Decision).

The voltage maintaining unit 51 holds the read voltage (VreadL or VreadH) obtained by the read operation of the memory cell MC as a discrimination target voltage. As described above, the read operation of the data stored in the memory cell MC may be referred to as a “first read operation.” In this case, it can be said that the voltage maintaining unit 51 holds the discrimination target voltage obtained by the first read operation.

After the first read operation, a write operation to the variable resistance element 101 is performed. This write operation may be referred to as a “first write operation.” The variable resistance element 101 is switched to the low resistance state or the high resistance state by the first write operation. After the first write operation, a second read operation is performed on the memory cell MC where the first write operation has been performed. The voltage obtained by the second read operation may be referred to as a “reference voltage.” The voltage maintaining unit 51 holds the reference voltage obtained by the second read operation.

The comparison unit 52 compares the discrimination target voltage held by the voltage maintaining unit 51 with the reference voltage. For example, the reference voltage is set to be a value obtained by multiplying the sum of the read voltage VreadL when the variable resistance element 101 is in the low resistance state and the read voltage VreadH when the variable resistance element 101 is in the high resistance state by ½ (a voltage substantially intermediate between the voltage VreadL and the voltage VreadH).

The discrimination unit 53 discriminates the resistance state of the variable resistance element 101 based on a comparison result obtained by the comparison unit 52. Specifically, in the case where the discrimination target voltage is smaller than the reference voltage, it is discriminated that the variable resistance element 101 is in the low resistance state. On the other hand, in the case where the discrimination target voltage is larger than the reference voltage, it is discriminated that the variable resistance element 101 is in the high resistance state.

### 1-7. Read Operation

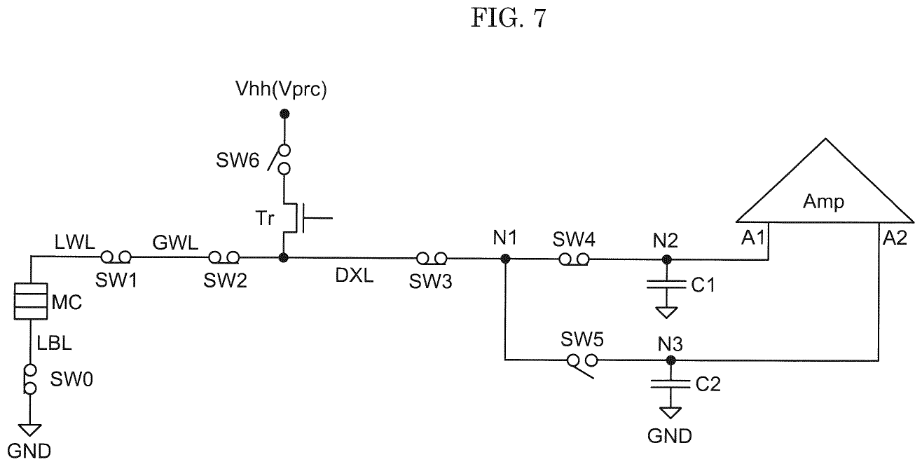

A read operation of the semiconductor storage device will be described with reference to FIG. 7. FIG. 7 is a circuit diagram for explaining a read operation of the semiconductor storage device according to an embodiment. The following operations and functions are realized by a processor provided in the control circuit 40 executing a program stored in the memory.

In the configuration shown in FIG. 7, the memory cell MC is provided between the local bit line LBL and the local word line LWL. A ground voltage GND is supplied to the local bit line LBL via a switching element SW0. In the case where the switching element SW0 is in an on-state, the ground voltage GND is supplied to the local bit line LBL, and in the case where the switching element SW0 is in an off-state, a voltage Vusel is supplied to the local bit line LBL. For example, the voltage Vusel is a voltage about half the threshold voltage Vth.

A switching element SW1 is provided between the local word line LWL and the global word line GWL. A switching element SW2 is provided between the global word line GWL and a data X-direction wiring DXL. A switching element SW3 is provided between the data X-direction wiring DXL and a node N1.

A sense amplifier Amp includes a terminal A1 and a terminal A2. A node N2 is connected to the terminal A1. A capacitive element C1 is connected to the Node N2. The capacitive element C1 holds a voltage of the node N2. A switching element SW4 is provided between the node N1 and the node N2. A node N3 is connected to the terminal A2. A capacitive element C2 is connected to the Node N3. The capacitive element C2 holds a voltage of the node N3. A switching element SW5 is provided between the node N1 and the node N3.

A switching element SW6 and a transistor Tr are connected in series between the data X-direction wiring DXL and a power line Vhh. A high-voltage for precharging the local word line LWL, the global word line GWL, and the data X-direction wiring DXL is supplied to the power line Vhh. The voltage supplied to the power line Vhh may be referred to as a “first voltage Vprc.” For example, the first voltage Vprc is determined based on the threshold voltage Vth of the switching element 102 of the memory cell MC. Specifically, the first voltage Vprc is [Vth+5σ×Vth] and is about twice the voltage of the voltage Vusel. Of course, the first voltage Vprc is not limited to the above value. It is sufficient that the switching elements SW1 to SW6 can be switched between the on-state and the off-state, and an NMOS or a PMOS is used.

As shown in FIG. 7, in the first read operation, the switching elements SW0 to SW4 are controlled to be in the on-state, and the local word line LWL connected to the memory cell MC that is the target of the read operation is connected to the node N2. On the other hand, the switching elements SW5 and SW6 are controlled to be in the off-state. When the switching element SW6 is controlled to be in the off-state, the local word line LWL, the global word line GWL, and the data X-direction wiring DXL are controlled to be in a floating state. Since the switching elements are controlled as described above, a voltage caused by the resistance state of the memory cell MC is supplied to the node N2. That is, the voltage to be supplied to the node N2 is determined by the resistance state of the memory cell MC, and the discrimination target voltage based on the resistance state of the memory cell is held in the capacitive element C1.

After the first read operation, the first write operation to the low resistance state or the high resistance state is performed on the memory cell MC that is the target of the read operation. In the case where the first write operation is performed, the switching element SW3 is controlled to be in the off-state, and the switching elements SW1, SW2, and SW6 are controlled to be in the on-state, so that the voltage Vprc required for the first write operation is supplied from the power line Vhh to the local word line LWL, the global word line GWL, and the data X-direction wiring DXL. Further, in the first write operation, the switching element SW0 is controlled to be in the on-state, whereby the voltage Vprc is applied to the memory cell MC. After the first write operation, the following second read operation is performed.

In the second read operation, the switching elements SW0 to SW3, and SW5 are controlled to be in the on-state, and the local word line LWL connected to the memory cell MC that is the target of the read operation is connected to the node N3. On the other hand, the switching elements SW4 and SW6 are controlled to be in the off-state. Although details will be described later, a voltage depending on the resistance state (low resistance state or high resistance state) of the memory cell MC obtained by the above-described first write operation is supplied to the node N3. That is, the voltage supplied to the node N3 is determined by the resistance state of the memory cell MC, and the reference voltage based on the resistance state of the memory cell is held in the capacitive element C2.

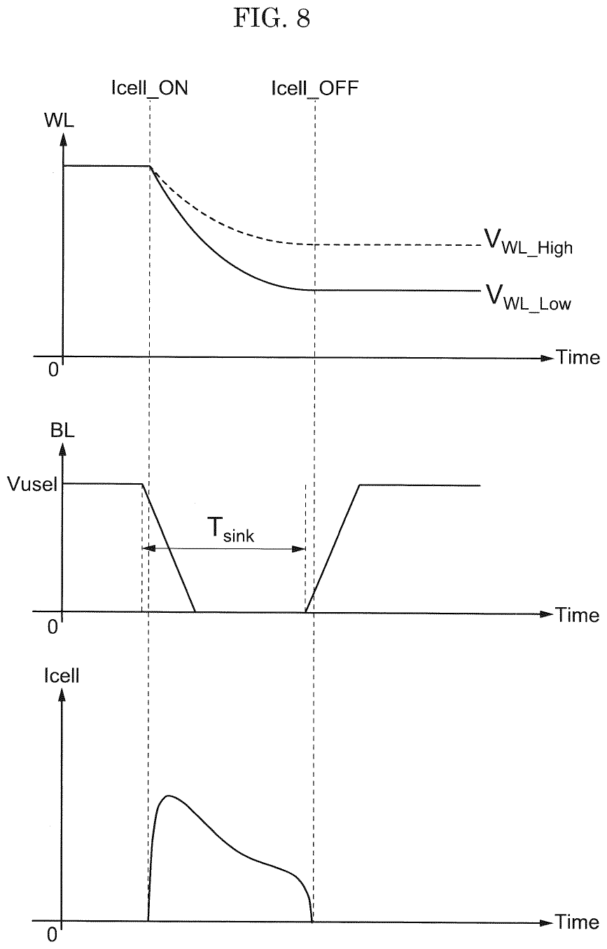

A change over time of each of a voltage (WL) of the local word line LWL, a voltage (BL) of the local bit line LBL, and a memory cell current (Icell) supplied to the memory cell MC in the first read operation will be described with reference to FIG. 8. In the following explanation, the local word line LWL may be simply referred to as the word line WL. Similarly, the local bit line LBL may be simply referred to as the bit line BL. An upper graph of FIG. 8 shows the change in the voltage of the word line WL over time. In the upper graph of FIG. 8, a solid line indicates a change over time in the case where the resistance state of the memory cell MC is in the low resistance state, and a dotted line indicates a change over time in the case where the resistance state of the memory cell MC is in the high resistance state. A middle graph of FIG. 8 shows a change in the voltage of the bit line BL over time. A lower graph of FIG. 8 shows a change in the memory cell current over time.

In the case where the voltage supplied to the bit line BL is Vusel (a voltage of about half the threshold voltage Vth), the memory cell MC is controlled to be in the non-conductive state. Therefore, almost no current flows through the memory cell MC. In other words, in this state, the word line WL is in the floating state. Therefore, the voltage of the word line WL does not change. With the word line WL floating, the switching element SW0 is switched from the off-state to the on-state. By this operation, the voltage supplied to the bit line BL is switched from Vusel to the grounded voltage GND (e.g., 0 V).

In this case, the voltage Vusel is a voltage for controlling the memory cell MC to be in the non-conductive state. This voltage Vusel may be referred to as a “first voltage.” The ground voltage GND is a voltage for controlling the memory cell MC to be in the conductive state. This ground voltage GND may be referred to as a “second voltage.”

As described above, by switching the voltage supplied to the bit line BL from the first voltage to the second voltage with the word line WL floating, the voltage of the bit line BL decreases. When the potential difference between the word line WL and the bit line BL exceeds the threshold voltage Vth of the memory cell MC, the memory cell MC is switched to the conductive state. Therefore, the memory cell current Icell flows through the memory cell MC, and the voltage of the word line WL gradually decreases (Icell_ON).

After the switching element SW0 is switched to the ON state and a sensing time Tₛᵢₙₖ has elapsed, the switching element SW0 is switched from the ON state to the OFF state. By this operation, the voltage supplied to the bit line BL is switched from the ground voltage GND (e.g., 0 V) to the voltage Vusel.

In this case, the voltage Vusel is a voltage for controlling the memory cell MC to be in the non-conductive state. The voltage Vusel supplied after the ground voltage GND (second voltage) is supplied to the bit line BL may be referred to as a “third voltage.”

As described above, by switching the voltage supplied to the bit line BL from the second voltage to the third voltage after the sensing time Tsink has elapsed, the voltage of the bit line BL increases. When the potential difference between the word line WL and the bit line BL falls below the hold voltage Vhold, the memory cell MC is switched to the non-conductive state. Therefore, the current flowing through the memory cell MC decreases, and the decrease of the voltage of the word line WL stops (I_{cell_OFF}). In this case, since the word line WL is in the floating state, the voltage of the word line WL is maintained at a predetermined voltage.

The voltage of the word line WL is different between the case where the memory cell MC is in the high resistance state and the case where the memory cell is in the low resistance state. The voltage (V_{WL_High}) (in the case of the dotted line) after the sensing time Tₛᵢₙₖ has elapsed in the case where the memory cell MC is in the high resistance state is higher than the voltage (V_{WL_Low}) (in the case of the solid line) after the sensing time Tₛᵢₙₖ has elapsed in the case where the memory cell MC is in the low resistance state.

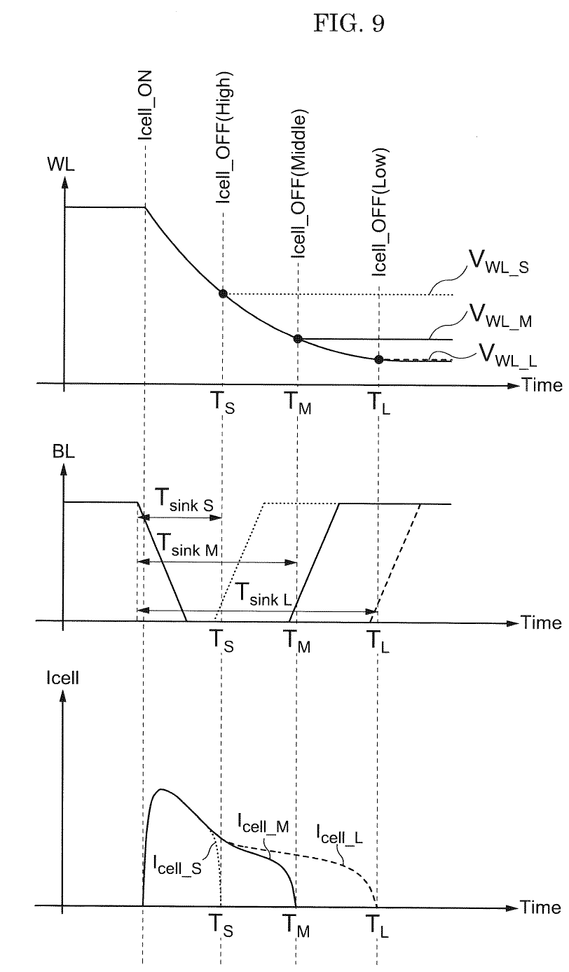

Next, a method for adjusting the voltage of the word line WL in the second read operation will be described with reference to FIG. 9. FIG. 9 shows a change over time of each of the voltage of the word line WL, the voltage of the bit line BL, and the memory cell current I_{cell} in the second read operation in the case where the memory cell MC is controlled to be in the low resistance state by the first write operation. In FIG. 9, three types of sensing times Tₛᵢₙₖ (T_{sink S}, T_{sink M}, T_{sink L}) are shown. The shortest sensing time is T_{sink S}. The longest sensing time is T_{sink L}. An intermediate of these sensing times is T_{sink M}. The memory cell currents corresponding to each of the sensing times T_{sink S}, T_{sink M}, T_{sink L} are I_{cell_S}, I_{cell_M}, I_{cell_L}.

In FIG. 9, in the case where the sensing time is T_{sink S} (the voltage of the bit line BL indicated by the dotted line), the memory cell current I_{cell_S} is interrupted at the time T_{S}. Therefore, the voltage decrease of the word line WL stops at a voltage V_{WL_S} (I_{cell_OFF} (High)). In the case where the sensing time is T_{sink M} (the voltage of the bit line BL indicated by the solid line), the memory cell current I_{cell_M} is interrupted at a time T_{M}. Therefore, the voltage decrease of the word line WL stops at a voltage V_{WL_M} (I_{cell_OFF} (Middle)). In the case where the sensing time is T_{sink L} (the voltage of the bit line BL indicated by a broken line), the memory cell current I_{cell_L} is interrupted at a time T_{L}. Therefore, the voltage decrease of the word line WL stops at a voltage V_{WL_L} (I_{cell_OFF} (Low)). As described above, by adjusting the length of the sensing time, the voltage of the word line WL after the second read operation can be adjusted.

In the case where the behavior of the word line WL is known in advance for the memory cell MC controlled to be in the low resistance state or the high resistance state by the first write operation, the voltage of the word line WL after the second read operation can be arbitrarily set by adjusting the length of the sensing time. A reference voltage can be obtained by this method.

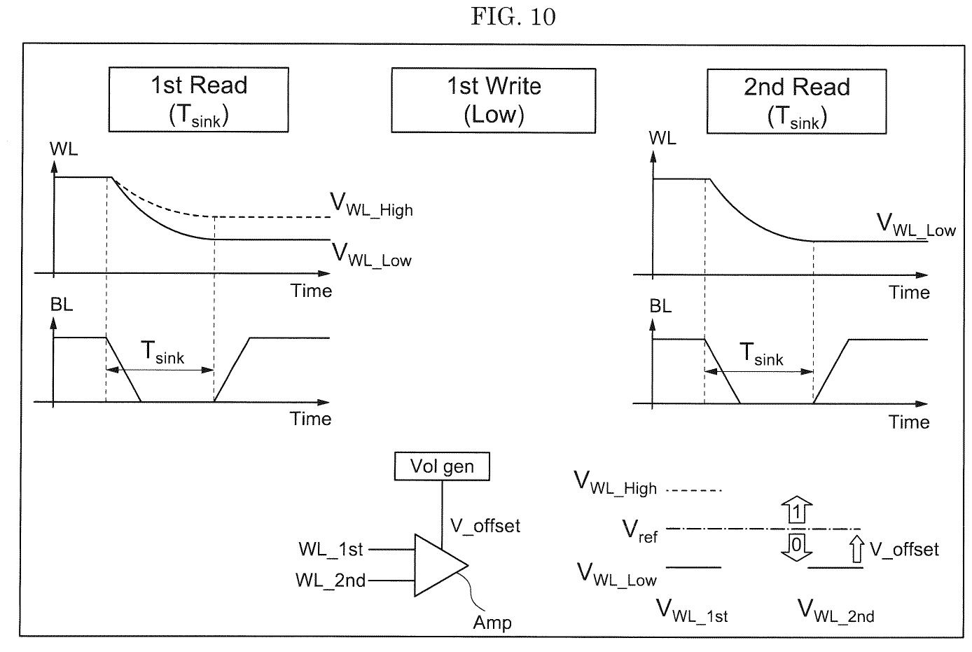

A read operation in the semiconductor storage device of the comparative example will be described with reference to FIG. 10. FIG. 10 is a diagram illustrating the read operation of the semiconductor storage device of the comparative example. FIG. 10 exemplifies a configuration in which the first read operation (1st Read (Tₛᵢₙₖ)) is performed and then the first write operation (1st Write (Low)) is performed to control the memory cell MC to the low resistance state, and the second read operation (2nd Read (Tₛᵢₙₖ)) is performed. In FIG. 10, the sensing time Tₛᵢₙₖ of the first read operation and the sensing time Tₛᵢₙₖ of the second read operation are the same.

Since the First Read Operation Shown in FIG. 10 Is the Same As the First Read Operation Shown in FIG. 8, the description thereof will be omitted. As described above, since the memory cell MC is controlled to be in the low resistance state in the first write operation, the same behavior as the solid line (V_{WL_Low}) of the first read operation (1st Read (Tₛᵢₙₖ)) is shown in the second read operation. The sense amplifier Amp determines a reference voltage V_{ref} by supplying an offset voltage V_offset to the voltage V_{WL_Low} detected by the second read operation. The reference voltage V_{ref} is a voltage that is substantially intermediate between the voltage V_{WL_High} and the voltage V_{WL_Low}. The sense amplifier Amp calculates a difference (first difference) between the voltage detected by the first read operation and the voltage detected by the second read operation, and calculates a difference (second difference) between the voltage detected by the second read operation and the reference voltage V_{ref}. After that, the sense amplifier Amp compares the first difference with the second difference to determine whether the voltage detected by the first read operation is “0 (low resistance state)” or “1 (high resistance state).” Specifically, the sense amplifier Amp determines that the result of the first read operation is “0 (low resistance state)” when the first difference is smaller than the second difference, and determines that the result of the first read operation is “1 (high resistance state)” when the first difference is larger than the second difference.

However, in the semiconductor storage device of the above-described comparative example, since the offset voltage V_offset needs to be supplied to the sense amplifier Amp, a voltage generation circuit (Vol gen) for that purpose is required.

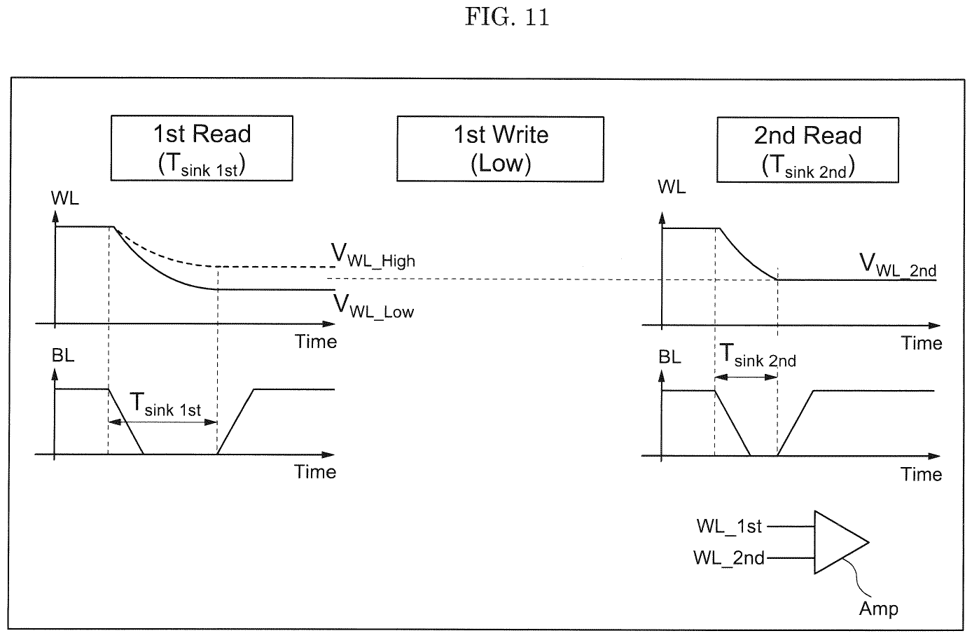

The read operation in the semiconductor storage device according to the present embodiment will be described with reference to FIG. 11. FIG. 11 is a diagram illustrating the read operation of the semiconductor storage device according to an embodiment. FIG. 11 is similar to FIG. 10, but differs from FIG. 10 in that a sensing time T_{sink_1st} of the first read operation differs from a sensing time T_{sink_2nd} of the second read operation. In the example of FIG. 11, the sensing time T_{sink_2nd} is shorter than the sensing time T_{sink_1st}.

As shown in FIG. 11, first, the first read operation (1st Read (T_{sink_1st})) during the sensing time T_{sink_1st} is performed. Since the first read operation is the same as the read operation shown in FIG. 8, the description thereof will be omitted.

Next, the First Write Operation (1st Write (low)) for Writing the Memory Cell Mc, Where the First read operation was performed, to the first state is performed. In the present embodiment, the memory cell MC is controlled to be in the low resistance state by the first write operation. The state of the memory cell MC after the first write operation may be referred to as a “first state.” In the first write operation, the voltage required to write the memory cell MC to the low resistance state is supplied to the bit line BL and word line WL.

Next, the second read operation (2nd Read (T_{sink_2nd})) during the sensing time T_{sink_2nd}, which differs from the sensing time T_{sink_1st}, is performed on the memory cell MC where the first write operation was performed. Since the second read operation is the same as the first read operation except that the sensing time is different, the description thereof will be omitted.

As shown in FIG. 11, in the case where the memory cell MC is controlled to be in the low resistance state, the sensing time of the second read operation is shorter than the sensing time of the first read operation, so that a voltage V_{WL_2nd} of the word line WL after the second read operation is controlled to be a voltage intermediate between the voltage V_{WL_Low} and the voltage V_{WL_High} after the first read operation. This voltage V_{WL_2nd} is used as a reference voltage.

Finally, the state of the memory cell MC is discriminated by comparing the first read result (V_{WL_Low} or V_{WL_High}) obtained by the first read operation with the second read result (V_{WL_2nd}) obtained by the second read operation. That is, in the period of the second read operation, the state of the memory cell MC is discriminated based on the voltage of the word line WL after the ground voltage GND (the second voltage) is supplied to the bit line BL for the sensing time T_{sink_2nd}.

The sensing time T_{sink_1st} of the first read operation may be referred to as a “first sensing time.” The sensing time T_{sink_2nd} of the second read operation may be referred to as a “second sensing time.” A period during which the first read operation is performed may be referred to as a “first read period.” A period during which the second read operation is performed may be referred to as a “second read period.” In this case, the first sensing time is a part of the first read period, and the second sensing time is a part of the second read period. Similarly, a period during which the first write operation is performed may be referred to as a “first write period.”

As described above, according to the semiconductor storage device of the present embodiment, since there is no need to supply the offset voltage to the sense amplifier Amp, the voltage generation circuit and an offset circuit required for generating the reference voltage V_{ref} can be omitted. That is, the size of the circuit required for the read operation can be reduced.

### 2. Second Embodiment

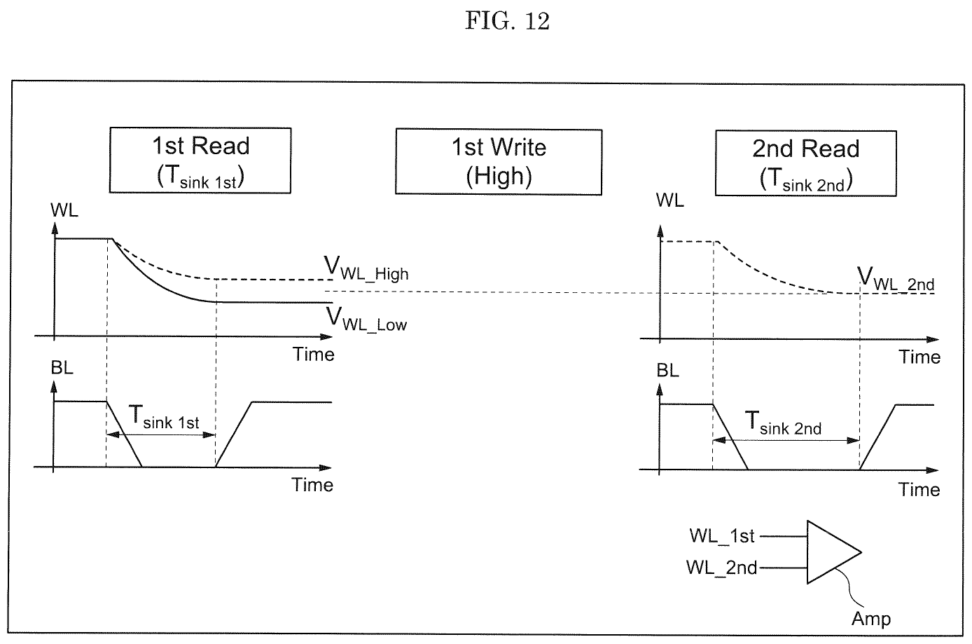

The semiconductor storage device 1 according to a second embodiment will be described with reference to FIG. 12. A configuration of the semiconductor storage device 1 according to the second embodiment is the same as the configuration of the semiconductor storage device 1 according to the first embodiment, but the read operations are different. In the following description of the second embodiment, descriptions of configurations similar to those of the first embodiment will be omitted, and differences from the first embodiment will be mainly described.

The read operation in the semiconductor storage device according to the present embodiment will be described with reference to FIG. 12. FIG. 12 is a diagram illustrating the read operation of the semiconductor storage device according to an embodiment. FIG. 12 is the same as FIG. 11 in that the sensing time T_{sink_1st} of the first read operation and the sensing time T_{sink_2nd} of the second read operation are different, but the first write operation controls the memory cell MC to be in the high resistance state, and the sensing time T_{sink_2nd} is longer than the sensing time T_{sink_1st}.

### 2-1. Read Operation

As shown in FIG. 12, first, the first read operation (1st Read (T_{sink_1st})) during the sensing time T_{sink_1st} is performed. Since the first read operation is the same as the read operation shown in FIG. 8 and FIG. 11, the description thereof will be omitted.

Next, the first write operation (1st Write (High)) for writing the memory cell MC, where the first read operation was performed, to the first state is performed. In the present embodiment, the memory cell MC is controlled to be in the high resistance state by the first write operation. The state of the memory cell MC after the first write operation can be referred to as the “first state” as in the first embodiment. That is, the first state may be the high resistance state as in the second embodiment, or may be the low resistance state as in the first embodiment. In the first write operation, a voltage required to write the memory cell MC to the high resistance state is supplied to the bit line BL and the word line WL.

Next, the second read operation (2nd Read (T_{sink_2nd})) of the sensing time T_{sink_2nd}, which differs from the sensing time T_{sink_1st}, is performed on the memory cell MC where the first write operation was performed. Since the second read operation is the same as the first read operation except that the sensing time is different, the description thereof will be omitted.

As shown in FIG. 12, in the case where the memory cell MC is controlled to be in the high resistance state, the sensing time of the second read operation is longer than the sensing time of the first read operation, so that the voltage V_{WL_2nd} of the word line WL after the second read operation becomes a voltage intermediate between the voltage V_{WL_Low} and the voltage V_{WL_High} after the first read operation. This voltage V_{WL_2nd} is used as a reference voltage.

Finally, the state of the memory cell MC is discriminated by comparing the first read result (V_{WL_Low} or V_{WL_High}) obtained by the first read operation with the second read result (V_{WL_2nd}) obtained by the second read operation. That is, in the period of the second read operation, the state of the memory cell MC is discriminated based on the voltage of the word line WL after the ground voltage GND (the second voltage) is supplied to the bit line BL for the sensing time T_{sink_2nd}.

As described above, according to the semiconductor storage device of the present embodiment, effects similar to those of the semiconductor storage device of the first embodiment can be obtained.

Although the present disclosure has been described above with reference to the drawings, the present disclosure is not limited to the embodiments described above and can be modified as appropriate without departing from the spirit of the present disclosure. For example, the addition, deletion, or design change of components as appropriate by those skilled in the art based on the semiconductor storage device of the present embodiment are also included in the scope of the present disclosure as long as they are provided with the gist of the present disclosure. Furthermore, each of the embodiments described above as an embodiment of the present invention can be appropriately combined and implemented as long as no contradiction is caused.

Further, it is understood that, even if the effect is different from those provided by each of the above-described embodiments, the effect obvious from the description in the specification or easily predicted by persons ordinarily skilled in the art is apparently derived from the present disclosure.

What is claimed is:

1. A semiconductor storage device comprising:
a first wiring;
a second wiring;
a memory cell configured to be electrically connected to the first wiring and the second wiring between the first wiring and the second wiring;
a sense amplifier configured to be electrically connected to the second wiring and configured to perform a read operation on the memory cell; and
a control circuit,
wherein the control circuit is configured to perform;
a first read operation during a first sensing time in a first read period,
a first write operation for writing the memory cell having undergone the first read operation to a first state in the first write period,
a second read operation during a second sensing time different from the first sensing time on the memory cell having undergone the first write operation in a second read period, and
a discrimination operation of a state of the memory cell by comparing a first read result obtained by the first read operation with a second read result obtained by the second read operation in a discrimination period.

2. The semiconductor storage device according to claim 1,
wherein
the control circuit is configured to;
switch a voltage supplied to the first wiring from a first voltage for controlling the memory cell to a non-conductive state to a second voltage for controlling the memory cell to a conductive state, and switch a voltage supplied to the first wiring after the first sensing time has elapsed from the second voltage to a third voltage for controlling the memory cell to the non-conductive state, as the first read operation, with the second wiring in a floating state,
supply a voltage for writing the memory cell to the first state to the first wiring and the second wiring, as the first write operation, and
switch a voltage supplied to the first wiring from the first voltage to the second voltage, and switch a voltage supplied to the first wiring after the second sensing time has elapsed from the second voltage to the third voltage, as the second read operation, with the second wiring in a floating state.

3. The semiconductor storage device according to claim 2,
wherein
the control circuit is configured to control the memory cell to a high resistance state or a low resistance state in the first write operation, and
the second sensing time is shorter than the first sensing time when the memory cell is controlled to the low resistance state by the first write operation.

4. The semiconductor storage device according to claim 2,
wherein
the control circuit is configured to control the memory cell to a high resistance state or a low resistance state in the first write operation, and
the second sensing time is longer than the first sensing time when the memory cell is controlled to the high resistance state by the first write operation.

5. The semiconductor storage device according to claim 2,
wherein
the control circuit is configured to discriminate a state of the memory cell based on a voltage of the second wiring after the second voltage is supplied to the first wiring for the second sensing time, in a period of the second read operation.

6. The semiconductor storage device according to claim 1,
wherein
the memory cell includes a variable resistance element and a switching element.

7. The semiconductor storage device according to claim 6,
wherein
the variable resistance element is a magnetoresistance effect element.
